(19) United States
(12) Patent Application Publication
(10) Pub. No.: US 2007/0023813 A1
(43) Pub. Date: Feb. 1, 2007

(54) SEMICONDUCTOR DEVICE HAVING UPPER ELECTRODE AND METHOD OF FABRICATING THE SAME

(75) Inventor: Dong-Hyun Han, Gyeonggi-do, (KR)

Correspondence Address: MARGER JOHNSON & MCCOLLOM, P.C., 210 SW MORRISON STREET, SUITE 400, PORTLAND, OR, 97204, US

(73) Assignee: Samsung Electronics Co., Ltd., Gyeonggi-Do (KR)

(21) Appl. No.: 11/383,152

(22) Filed: May 12, 2006

(30) Foreign Application Priority Data
Jul. 28, 2005 (KR) 2005-0069088

(51) Int. Cl. H01L 29/94

(52) U.S. Cl. 257/307

(57) ABSTRACT

An embodiment of the semiconductor device includes a semiconductor substrate having at least one cell region and a peripheral circuit region. An interlayer insulating layer is disposed on the semiconductor substrate. Storage node electrodes are disposed on the interlayer insulating layer of the cell region. An upper electrode is disposed to cover the substrate having the storage node electrodes, and has at least one opening exposing a predetermined portion of the peripheral circuit region. A planarized insulating layer is disposed over the upper electrode. Contact plugs are disposed to penetrate the planarized insulating layer, at least one opening of the upper electrode, and the interlayer insulating layer to be electrically connected to the semiconductor substrate.

### CROSS-REFERENCE TO RELATED APPLICATION

This application claims priority from Korean Patent Application No. 10-2005-0069088, filed on Jul. 28, 2005, the disclosure of which is hereby incorporated herein by reference in its entirety.

### BACKGROUND

1. Field of Invention

The present invention relates to a semiconductor device and a method of fabricating the same, and more particularly, to a semiconductor device having an upper electrode and a method of fabricating the same.

2. Description of the Related Art

Generally, the data storage capacity in a semiconductor memory device, such as dynamic random access memory (DRAM), which consists of one access transistor and one capacitor, depends on the capacitance of the capacitor. If the capacitance is small, a malfunction of reading out incorrect data may occur when the data, which is once stored, is read out. In order to prevent this malfunction, a refresh operation of restoring data at a predetermined time is necessary. Since the refresh operation is influenced by the capacitance of the capacitor, an increase of the capacitance may be one of the methods of improving the refresh characteristics. However, because recent trends of increasing the integration density of a semiconductor memory device results in a reduced area allowed for each unit cell of the chip, the area occupied by a capacitor is also significantly reduced, which in turn affects the capacitance.

In particular, the capacitance is proportional to the surface area where a storage electrode functioning as a lower electrode and a plate electrode functioning as an upper electrode face each other, and inversely proportional to the distance between the two electrodes. Therefore, in order to form a storage electrode having a large surface area in a limited space, a three-dimensional stack structure, such as a cylinder shape, a box shape, a fin shape, and the like have been proposed using a capacitor over bit-line (COB) process of forming a capacitor on a bit line. While the capacitance of the capacitor has been significantly increased by employing the three-dimensional stack structure capacitor, it causes the disadvantage of increasing a step height difference between a memory cell region where the stack type capacitor is formed, and a peripheral circuit region.

FIGS. 1A, 2A, 3A, and 4A are plan views illustrating a method of fabricating a conventional semiconductor device, and FIGS. 1B, 2B, 3B, and 4B are sectional views taken along a line of I-I′ of FIGS. 1A, 2A, 3A, and 4A, respectively.

Referring to FIGS. 1A and 1B, an isolation layer 102 is formed to confine active regions in a semiconductor substrate 100 having a cell region CL and a peripheral circuit region P. The isolation layer 102 may be formed using a trench isolation technique. An interlayer insulating layer 105 is formed on the semiconductor substrate 100. Buried contact plugs 110 are formed to penetrate the interlayer insulating layer 105 of the cell region CL and to be electrically connected to the active regions.

Storage node electrodes 115 are formed in the cell region CL to contact with the buried contact plugs 10 and protrude upwardly. A conformal dielectric layer is formed on the substrate having the storage node electrodes 115. Then, an upper electrode layer is formed on the substrate having the conformal dielectric layer. The upper electrode layer may be formed to fill the gap regions between the storage node electrodes 115.

The upper electrode layer and the dielectric layer are sequentially patterned, thereby forming a dielectric layer pattern 120 and an upper electrode 125 covering the storage node electrodes. At this time, edge portions E0 of the dielectric layer pattern 120 and the upper electrode 125 must be disposed so as not to cover the region where contacts will be formed. Thus, the edge portions E0 of the dielectric layer pattern 120 and the upper electrode 125 are disposed adjacent to the storage node electrodes 115.

An insulating layer 130 is formed on the substrate having the upper electrode 125. The insulating layer 130 is formed with a thickness greater than a height of the storage node electrode 115. While the insulating layer 130 is formed on the upper electrode 125 on the storage node electrodes 115 in the cell region CL, the insulating layer 130 is also formed on the interlayer insulating layer 105 in the peripheral circuit region P. Thus, the insulating layer 130 has a step height difference as thick as the sum of the height of the storage node electrode 115 and the thickness of the upper electrode. Thus, as shown in FIG. 1B, a step height difference region P0 of the insulating layer 130 is generated at the boundary portion of the cell region CL and the peripheral circuit region P, and a step height difference profile of the step height difference region P0 has a sharp point T1 profile. As an angle α of the sharp point T1 in the sharp point T1 profile is very small, that is, 100 degrees or lower, the sharp point T1 profile shows characteristic instabilities to the stresses of the exterior environment.

A portion B0 of the insulating layer 130 in the cell region CL may then be partially etched using photolithography and etch processes. This etching may be performed for the convenience of a subsequent process, such as a chemical mechanical polishing (CMP) process.

Referring to FIGS. 2A and 2B, the insulating layer 130 is planarized. As a result, a planarized insulating layer 130′ is formed. At this time, a crack C may be generated at the sharp point T1 region having the unstable characteristics. Metal contact holes 135h are then formed to penetrate the planarized insulating layer 130′ and the interlayer insulating layer 105 in the peripheral circuit region P to expose predetermined portions of the semiconductor substrate 100. The metal contact plugs 135 are formed to fill the metal contact holes 135h and contact the semiconductor substrate.

Referring to FIGS. 3A and 3B, a metal layer 140 is formed on the substrate having the metal contact plugs 135. The metal layer 140 may fill the crack C portion. As a result, a crack region C′, which is filled with metal, may be formed.

Referring to FIGS. 4A and 4B, the metal layer 140 is patterned, thereby forming metal interconnections M, M1, M2, M3 on the planarized insulating layer 130′. However, the interconnection indicated by the reference character ‘M1’, the interconnection indicated by the reference character ‘M2’, and the interconnection indicated by the reference character ‘M3’ are all electrically connected by the crack region C′ filled with metal, thereby causing interconnection failures.

Therefore, it is required to develop a method of fabricating a semiconductor device to prevent the generation of the crack C when planarizing the insulating layer by preventing generation of the sharp point T1 profile when forming the insulating layer.

### SUMMARY

Embodiments of the present invention are directed to a semiconductor device, which is structured to prevent generation of a sharp point profile when forming an insulating layer on a semiconductor substrate having a step height difference region.

Other embodiments of the present invention provide an upper electrode of a capacitor structured to prevent generation of a sharp point profile when forming an insulating layer on a semiconductor substrate having a three-dimensional stack type capacitor. A method of fabricating the upper electrode according to the above embodiments is also provided.

In accordance with an exemplary embodiment, the present invention provides a semiconductor device having an upper electrode. The semiconductor device includes a semiconductor substrate having at least one cell region and a peripheral circuit region. A plurality of cells are disposed on the semiconductor substrate of the cell region, and provide a step height difference region between the peripheral circuit region and the cell region. An upper electrode is disposed to cover the substrate having the cells, and has at least one opening exposing a predetermined portion of the peripheral circuit region. A planarized insulating layer is disposed on the substrate having the upper electrode. Contact plugs are disposed to penetrate the planarized insulating layer and at least one opening of the upper electrode, and to be electrically connected to the semiconductor substrate.

### BRIEF DESCRIPTION OF THE DRAWINGS

The above and other features and advantages of the present invention will become more apparent to those of ordinary skill in the art by describing in detail embodiments thereof with reference to the attached drawings in which:

FIGS. 1A, 2A, 3A, and 4A are plan views illustrating a method of fabricating a conventional semiconductor device;

FIGS. 1B, 2B, 3B, and 4B are sectional views taken along a line of I-I′ of FIGS. 1A, 2A, 3A, and 4A, respectively;

FIG. 5 is a layout of a semiconductor device having an upper electrode according to embodiments of the present invention;

FIGS. 6A, 7A, and 8A are sectional views illustrating a method of fabricating a semiconductor device taken along a line of II-II′ of FIG. 5;

FIGS. 6B, 7B, and 8B are sectional views illustrating a method of fabricating a semiconductor device taken along a line of III-III′ of FIG. 5; and

FIG. 9 is a layout of a semiconductor device having an upper electrode according to another embodiment of the present invention.

### DETAILED DESCRIPTION

The present invention will now be described more fully hereinafter with reference to the accompanying drawings, in which embodiments of the invention are shown. This invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the thicknesses of layers and regions are exaggerated for clarity. In addition, when a layer is described to be formed “on” another layer or on a substrate, the layer may be formed on the other layer or on the substrate, or one or more layers may be interposed between the layer and the other layer or the substrate. Like numbers refer to like elements throughout the specification.

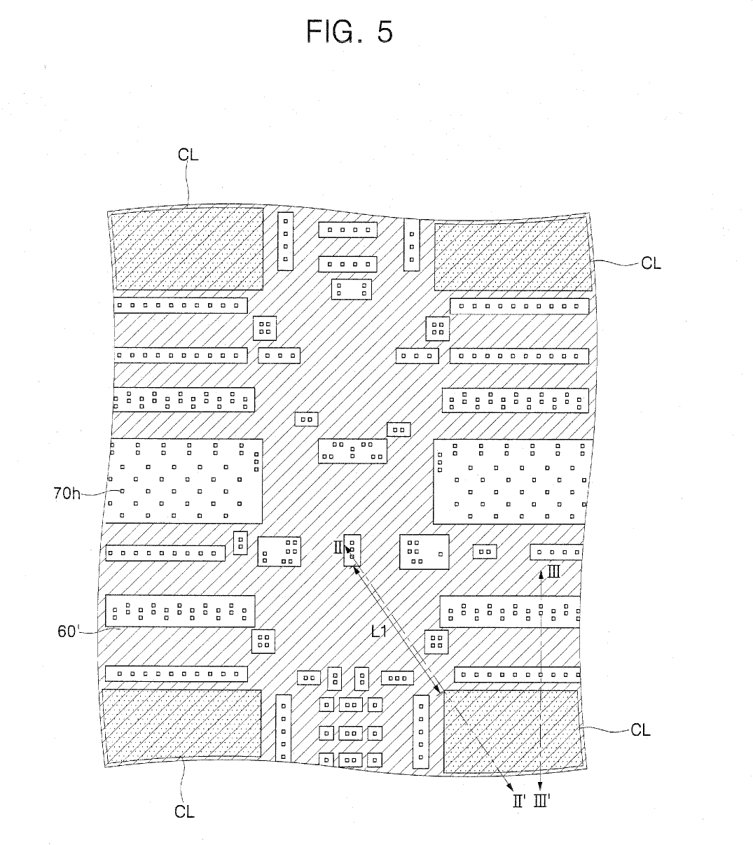

FIG. 5 is a layout of a semiconductor device having an upper electrode according to embodiments of the present invention.

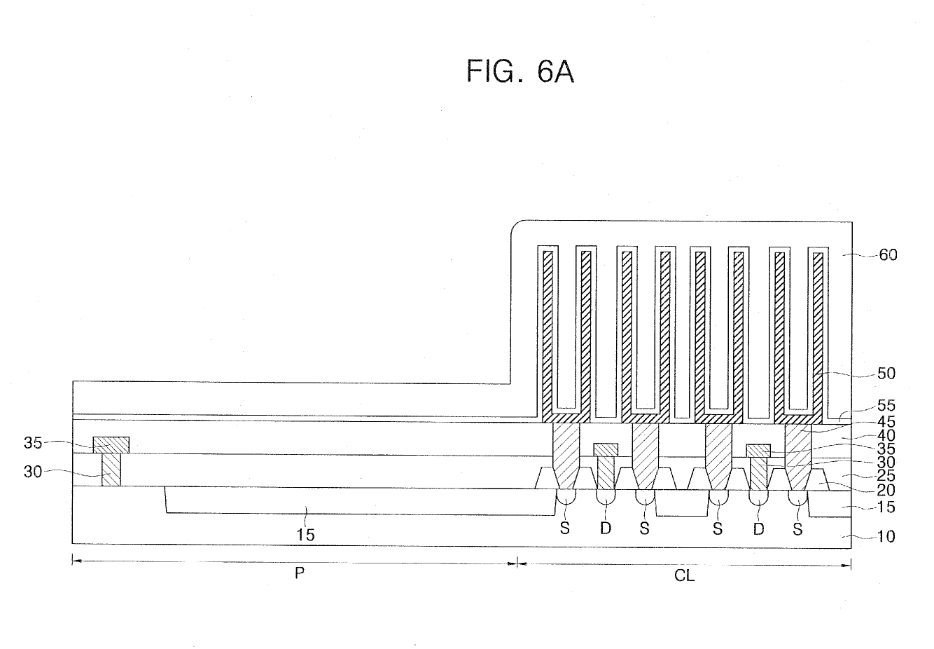

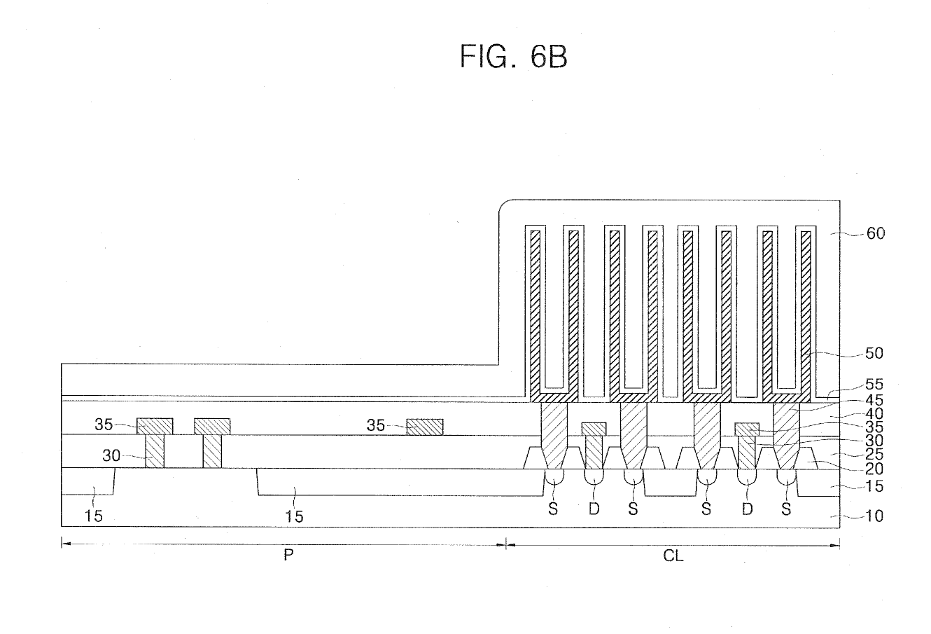

FIGS. 6A, 7A, and 8A are sectional views illustrating a method of fabricating a semiconductor device taken along a line of II-II′ of FIG. 5, and FIGS. 6B, 7B, and 8B are sectional views illustrating a method of fabricating a semiconductor device taken along a line of III-III′ of FIG. 5.

Referring to FIGS. 5, 6A, and 6B, an isolation layer 15 is formed to confine active regions inside a semiconductor substrate 10 having a cell region CL and a peripheral circuit region P. The isolation layer 15 may be formed using a trench isolation technique. Gates 20 are formed on the semiconductor substrate 10 to intersect the active regions. The gates 20 include gate patterns and gate spacers. The gate pattern includes a gate insulating layer pattern, a gate electrode, and a hard mask layer pattern, which are sequentially stacked. A source region S and a drain region D are formed in the semiconductor substrate 10, using the gates 20 as ion implantation masks.

A first interlayer insulating layer 25 is formed on the semiconductor substrate 10 having the source/drain regions S, D. Direct contact (DC) plugs 30 are formed to penetrate the first interlayer insulating layer 25 and to contact with the semiconductor substrate 10. At this time, the DC plugs 30 inside the cell region CL are formed to be electrically connected with the drain region D. Then, bit lines 35 are formed on the first interlayer insulating layer 25 to intersect over the DC plugs 30. The bit lines 35 may be formed to extend to the peripheral circuit region P. The DC plugs 30 and the bit lines 35 may be formed of tungsten layers.

A second interlayer insulating layer 40 is then formed on the semiconductor substrate 10 having the bit lines 35. The second interlayer insulating layer 40 and the first interlayer insulating layer 25 are sequentially patterned, using photolithography and etch processes, to form contact holes exposing the source regions S inside the cell region CL. Then, buried contact (BC) plugs 45 are formed to fill the contact holes.

A three-dimensional structure of storage electrodes, which contact the BC plugs 45 and are protruded upwardly, are formed on the second interlayer insulating layer 40 of the cell region CL. The storage electrodes may be formed as a cylinder shape, a box shape, or a fin shape. In this embodiment, cylinder-shaped storage node electrodes 50 are formed. A conformal dielectric layer 55 is formed on the substrate 10 having the storage node electrodes 50. An upper electrode layer 60 is then formed on the substrate 10 having the conformal dielectric layer 55. The upper electrode layer is formed to fill the gap regions between the storage node electrodes 50.

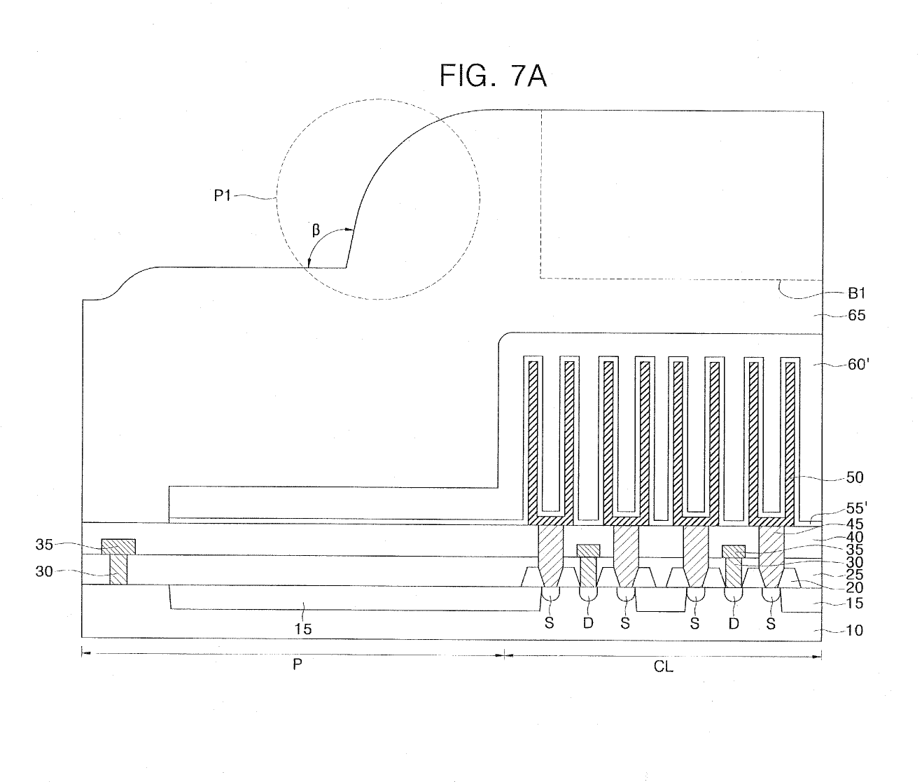

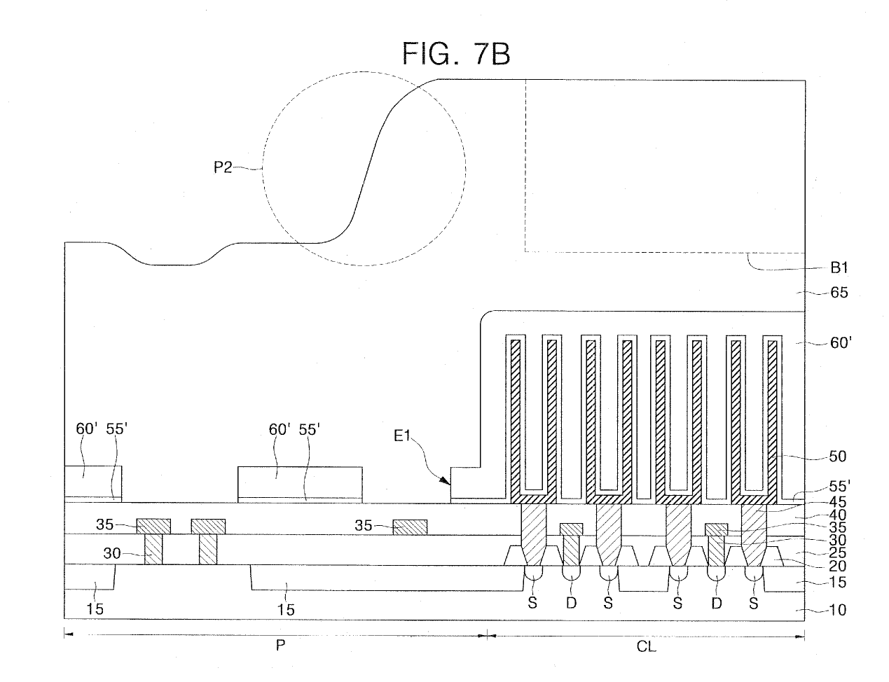

Referring to FIGS. 5, 7A, and 7B, the upper electrode layer 60 is patterned to form an upper electrode 60′ covering the substrate 10 having the storage node electrodes 50, and having openings exposing predetermined portions of the peripheral circuit regions P. The dielectric layer 55 is concurrently patterned, thereby forming a dielectric layer pattern 55′. The upper electrode 60′ may be formed as one electrode in the cell regions CL and the peripheral circuit region P as shown in FIG. 5. Thus, when a voltage is applied to the upper electrode 60′, the effective upper electrode of each of the cells in the cell region CL will have a constant voltage, which allows the cells to be maintained in a stable state without voltage fluctuations between cells. A reference character ‘L1’ of FIG. 5 refers to an extension length of the upper electrode 60′ extending at the corner portions of the cell regions CL.

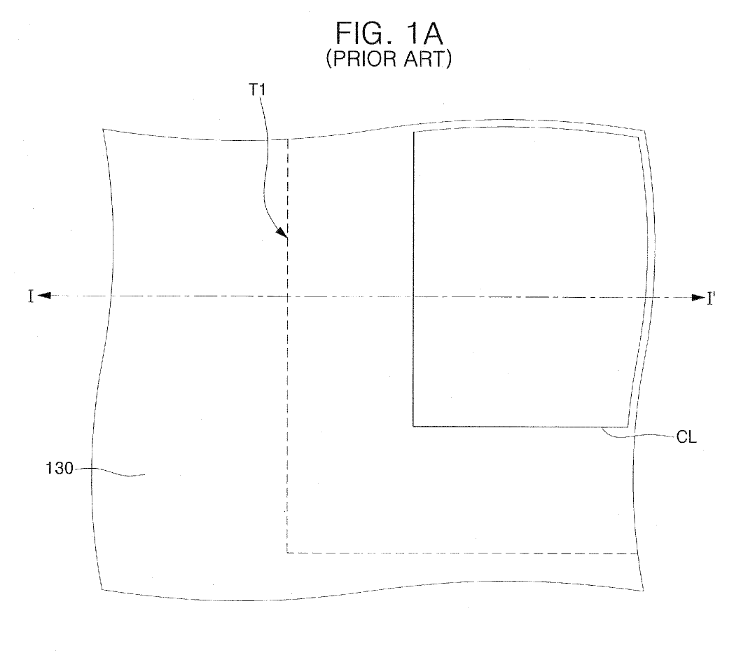

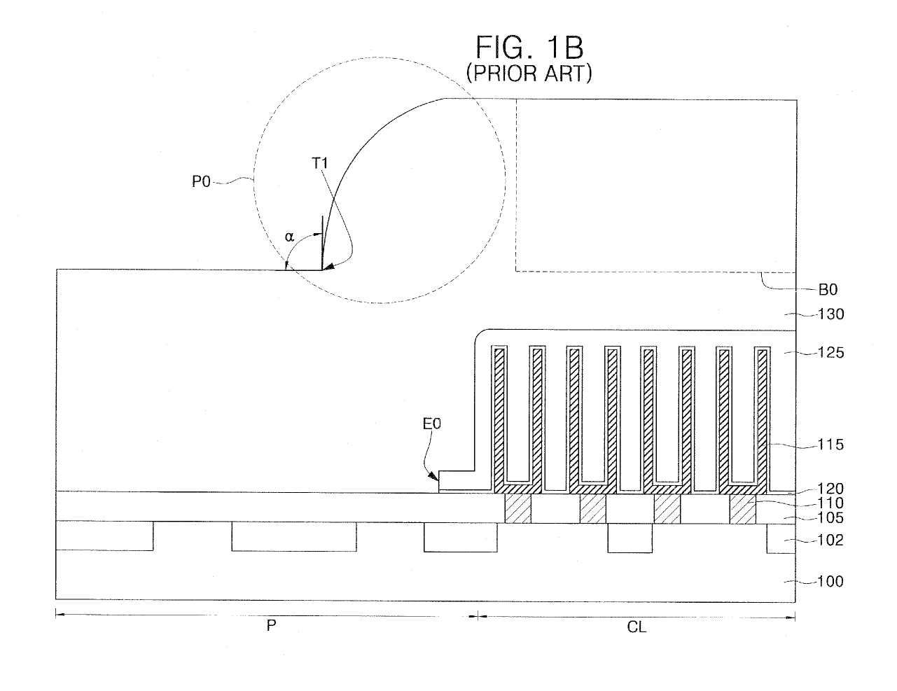

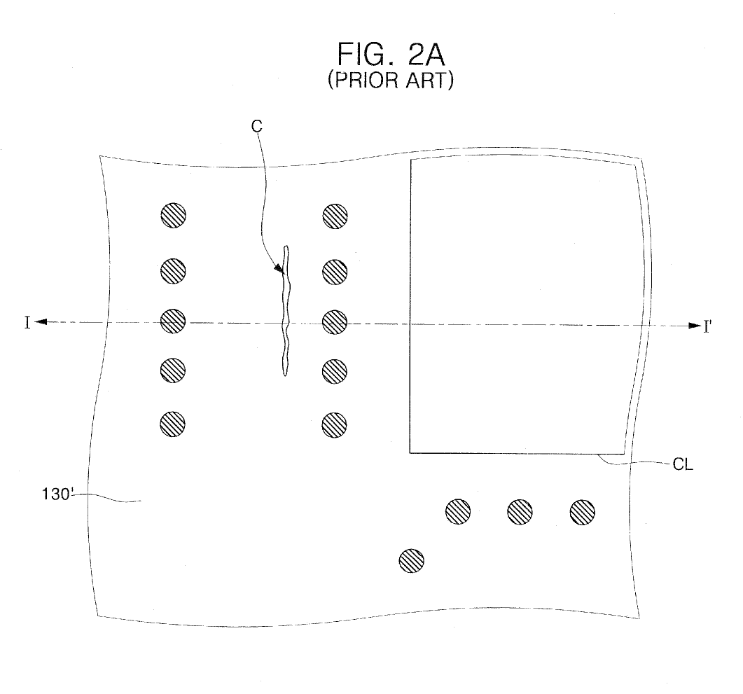

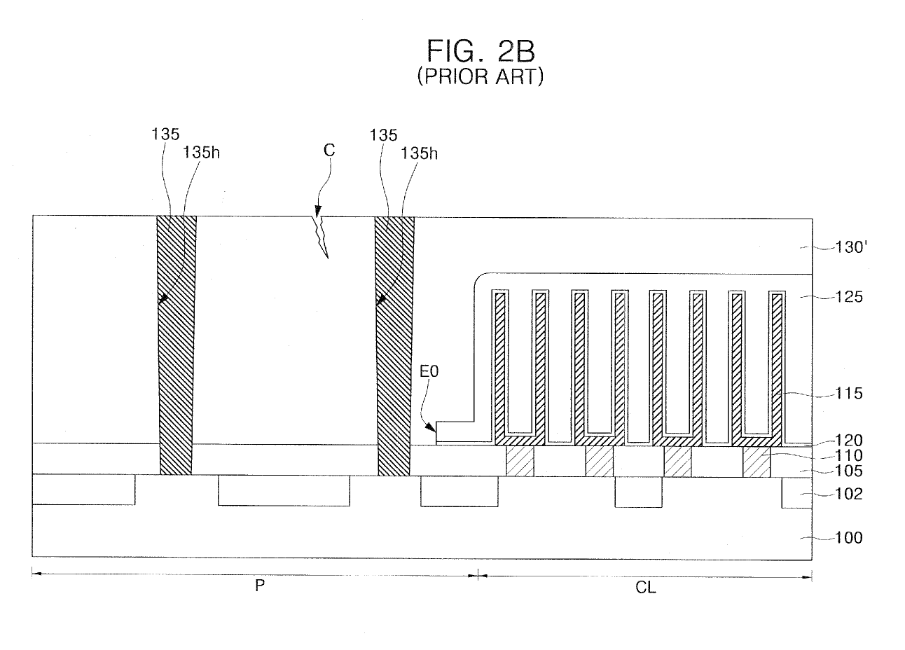

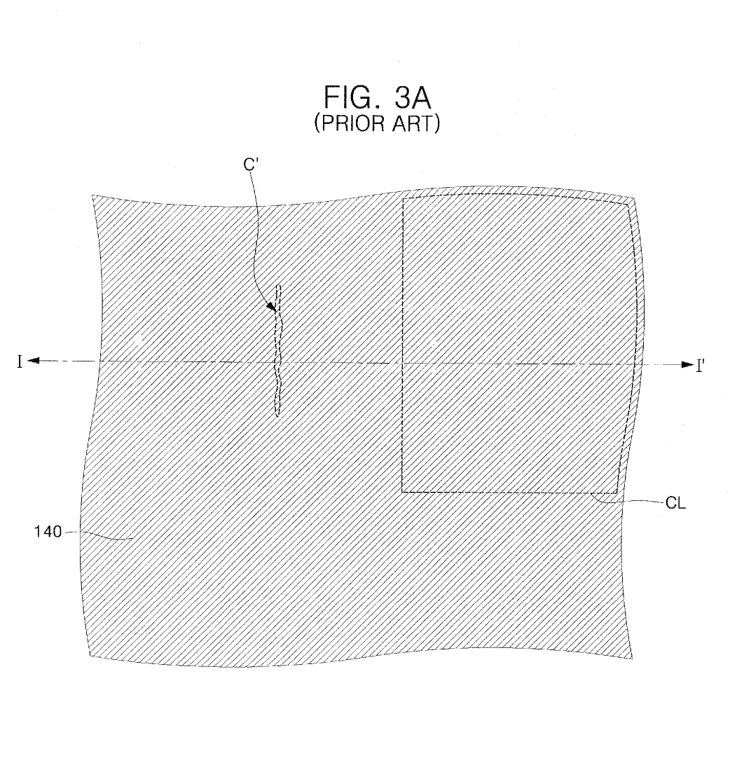

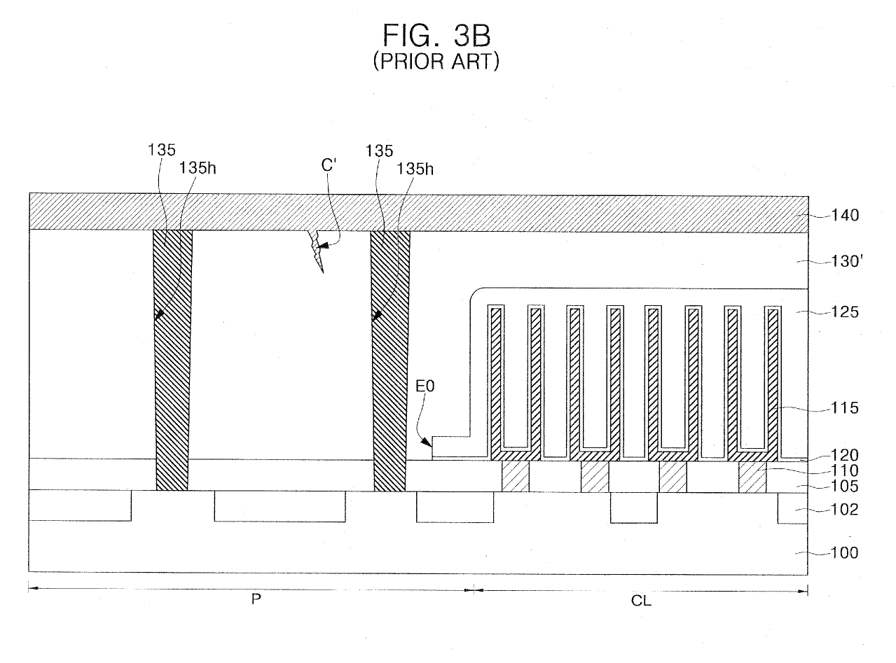

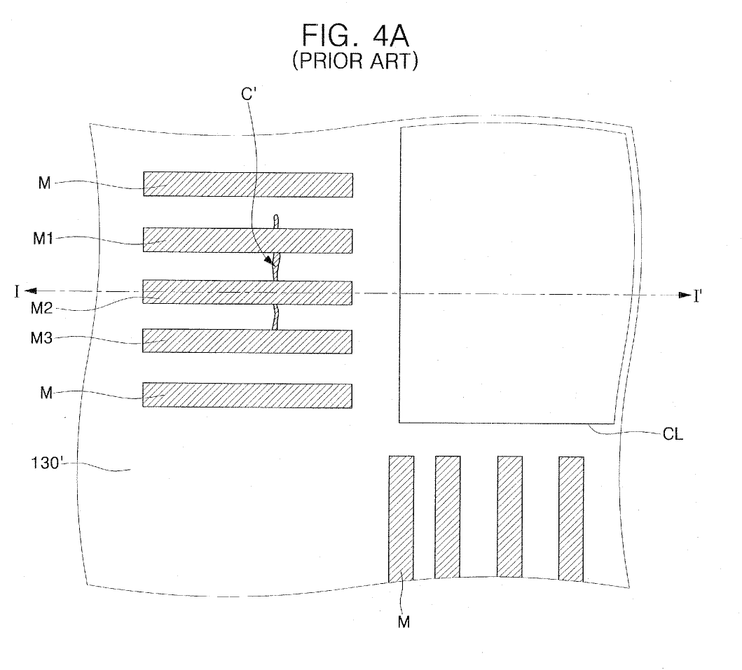

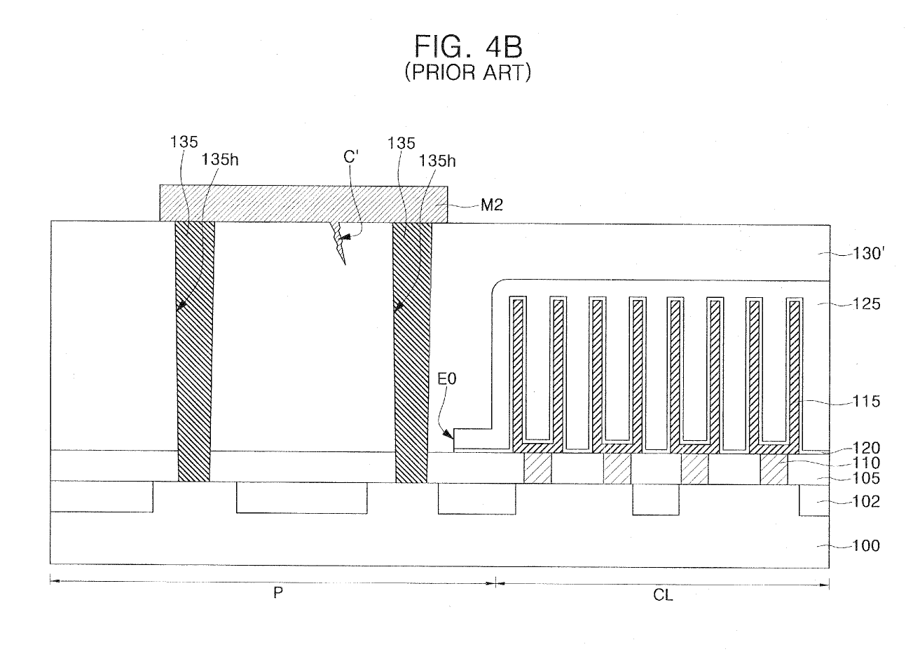

An insulating layer 65 is formed on the substrate 10 having the upper electrode 60′. The insulating layer 65 may be formed of an oxide layer. Preferably, the insulating layer 65 may be formed of plasma enhanced oxide (PE-Oxide), undoped silicate glass (USG), plasma enhanced tetraethyl orthosilicate (PE-TEOS), or high density plasma oxide (HDP-Oxide). The insulating layer 65 is formed with a thickness greater than a height of the storage node electrodes 50. At this time, the insulating layer 65 may have generated step height difference, but the step height difference is reduced by the upper electrode 60′ extending to the peripheral circuit region P as compared to that of the conventional case. Thus, an angle β of the step height difference profile of a step height difference region P1 of FIG. 7A is greater than an angle α of the sharp point T1 profile of FIG. 1B. As a result, the insulating layer 65 is formed to have very stable characteristics as compared to the conventional art having the sharp point T1 profile. This, in turn, allows the insulating layer 65 to be more stable against the stresses in a subsequent planarization process.

Further, as shown in FIG. 7B, an edge portion E1 of the upper electrode 60′ may be formed adjacent to the cell region CL resulting in a step height difference region P2 shown in FIG. 7B. However, unlike the conventional art, the step height difference profile of the step height difference region P2 may be formed as a smooth curve by forming the upper electrode 60′ so as to extend to the peripheral circuit region P. Thus, an insulating layer 65 may be formed to be stable against stress or the like.

A portion B1 of the insulating layer 65 of the cell region CL may then be partially etched using photolithography and etch processes. This etching may be performed for the convenience of subsequent fabrication processes, such as a chemical mechanical polishing (CMP) process.

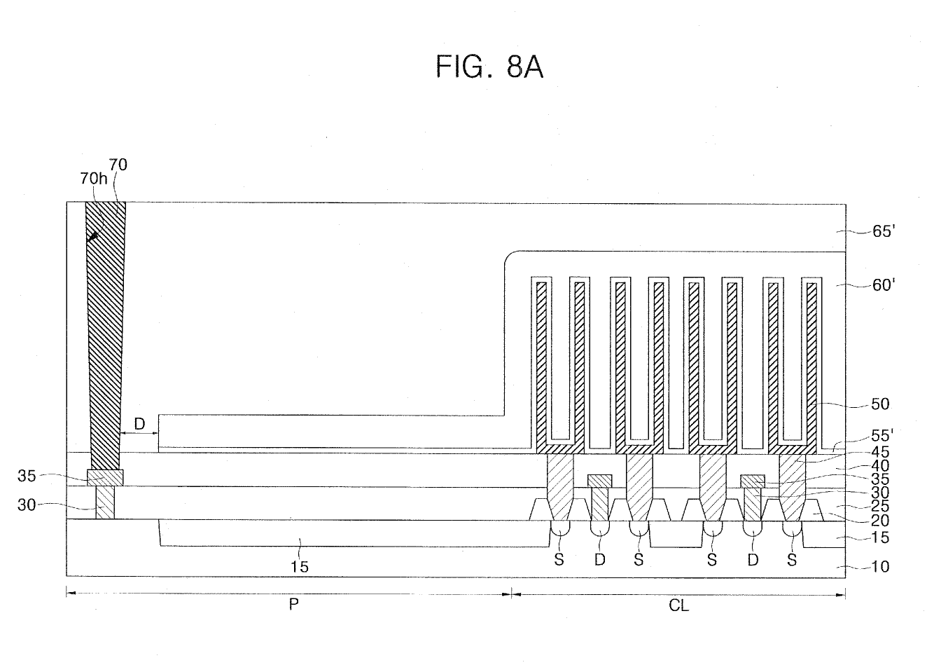

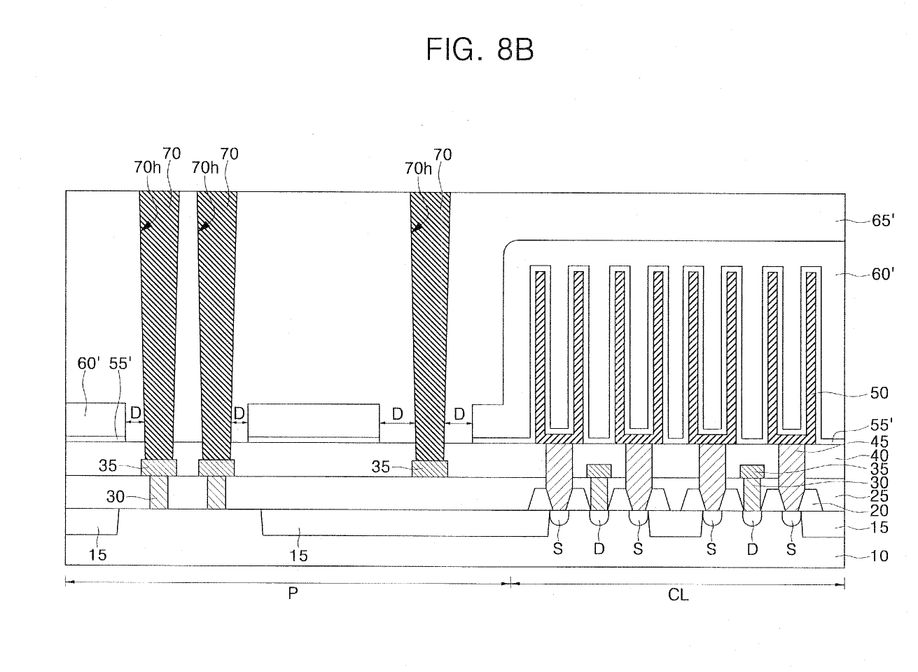

Referring to FIGS. 5, 8A and 8B, the insulating layer 65 is planarized. As a result, a planarized insulating layer 65′ is formed. The planarization process may be performed using a CMP process. The insulating layer 65 has a smooth curve profile at the step height difference region because the width of the step height difference is reduced by the upper electrode 60′ extending to the peripheral circuit region P, and thus, a phenomenon of crack generation due to stress during the planarization process or the like can be prevented.

Then, metal contact holes 70h are formed to penetrate the planarized insulating layer 65′ of the peripheral circuit region P, the openings of the upper electrode 60′, and the second interlayer insulating layer 40 to expose at least a portion of the bit lines 35. Metal contact plugs 70 are formed to fill the metal contact holes 70h and contact with at least the bit lines 35. The metal contact plugs 70 may then be formed in the contact holes 70h to be spaced from the upper electrode 60′ by a distance D of about 0.05 μm to about 0.5 μm. When designing the layout of the upper electrode 60′ as shown in FIG. 5, the positions where the metal contact plugs 70 are to be formed is considered.

The upper electrode 60′, the dielectric layer pattern 55′, and the storage node electrodes 50 constitute capacitor elements. At least one of the upper electrode 60′ and the storage node electrodes 50 may be formed of a polysilicon layer or a metal layer.

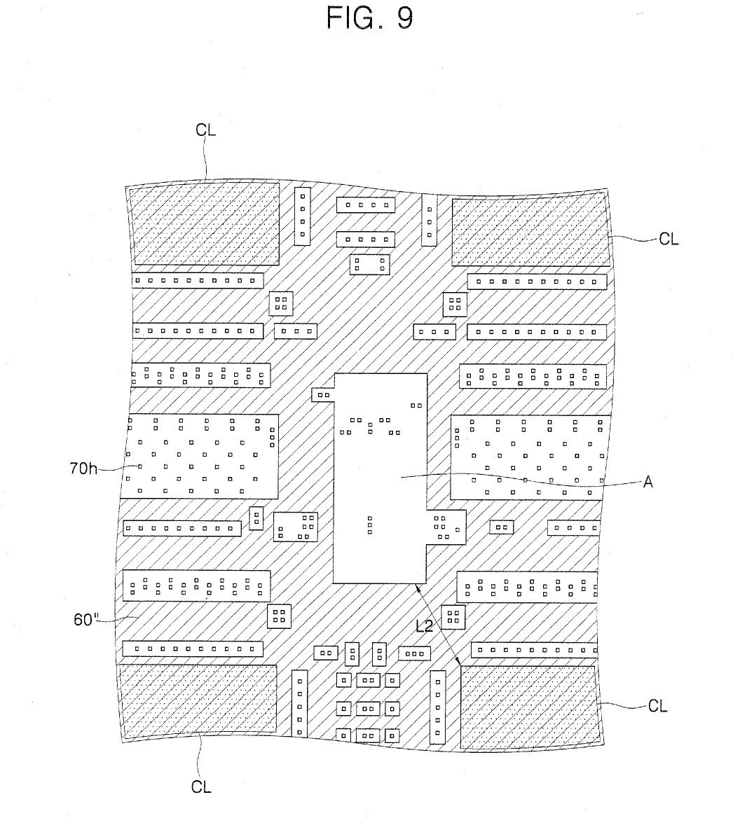

FIG. 9 is a layout of a semiconductor device having an upper electrode according to another embodiment of the present invention.

Referring to FIG. 9, an upper electrode 60″ may be formed to have a central opening A exposing a central portion of the peripheral circuit region, by changing a pattern shape of the upper electrode 60′ in the layout of FIG. 5. In this embodiment, the upper electrode 60″ of all the cell regions CL and the peripheral circuit region is formed as one electrode. A distance L2 between the edge portion of the central opening A and the cell region CL indicates the length of the upper electrode 60″ covering the cell region CL and extending to the peripheral circuit region. The distance L2 may be shorter than the reference distance L1 of FIG. 5, but is still long enough to prevent a sharp point profile during the formation of the insulating layer. The scope of the present invention includes the method of fabricating a semiconductor device using the layout of FIG. 9.

A semiconductor device including a capacitor having an upper electrode according to embodiments of the present invention will be explained in reference to FIGS. 5, 8A, and 8B again.

Referring to FIGS. 5, 8A, and 8B, an isolation layer 15 is disposed to confine active regions inside the semiconductor substrate 10 having the cell regions CL and the peripheral circuit region P. Gates 20 are disposed on the semiconductor substrate 10 to intersect the active regions. The gate 20 includes a gate pattern and a gate spacer. The gate pattern includes a gate insulating layer pattern, a gate electrode, and a hard mask layer pattern, which are sequentially stacked. Source regions S and drain regions D are disposed inside the active regions of the semiconductor substrate 10 adjacent to the gates 20.

A first interlayer insulating layer 25 is disposed on the semiconductor substrate 10 having the source/drain regions S and D. Direct contact (DC) plugs 30 are disposed to penetrate the first interlayer insulating layer 25 and to contact the semiconductor substrate 10. The DC plugs 30 inside the cell region CL are further disposed to be electrically connected to the drain region D. Bit lines 35 are disposed on the first interlayer insulating layer 25 to intersect over the DC plugs 30. The DC plugs 30 and the bit lines 35 may be tungsten layers.

A second interlayer insulating layer 40 is then disposed on the semiconductor substrate 10 having the bit lines 35. Buried contact (BC) plugs 45 are disposed to penetrate the second interlayer insulating layer 40 and the first interlayer insulating layer 25, and to contact the source region S inside the cell region CL.

A three-dimensional structure of storage electrodes, which contact the BC plugs 45 and are protruded upwardly, are disposed on the second interlayer insulating layer 40 of the cell region CL. The storage electrodes may have a cylinder shape, a box shape, or a fin shape. However, in this embodiment of the present invention, cylinder-shaped storage node electrodes 50 are illustrated.

An upper electrode 60′ is disposed on the substrate 10 having the storage node electrodes 50, and to have openings exposing predetermined portions of the peripheral circuit regions P. As shown in FIG. 5, one upper electrode 60′ is disposed in the cell regions CL and the peripheral circuit region P. Thus, since the upper electrode 60′ of all the cells inside the cell regions CL can have a constant voltage applied across all of the cells, a stable state can be maintained between cells without voltage fluctuations between the cells. The upper electrode 60′ may be a structure filling the gap regions between the storage node electrodes 50.

A planarized insulating layer 65′ is disposed on the substrate 10 having the upper electrode 60′. The planarized insulating layer 65′ may be an oxide layer. Preferably, the planarized insulating layer 65′ may be a plasma enhanced oxide (PE-Oxide), undoped silicate glass (USG), plasma enhanced tetraethyl orthosilicate (PE-TEOS), or high density plasma oxide (HDP-Oxide) layer. Metal contact holes 70h penetrating the planarized insulating layer 65′, the openings of the upper electrode 60′, and the second interlayer insulating layer 40, to expose at least a portion of the bit lines 35. Metal contact plugs 70 are disposed in the metal contact holes 70h, may be spaced from the upper electrode 60′. A distance D between the metal contact plugs 70 and the upper electrode 60′ may be about 0.05 μm to about 0.5 μm. This is designed to consider the positioning of the metal contact plugs 70 to the desired layout of the upper electrode 60′ as shown in FIG. 5.

A dielectric layer pattern 55′ may be interposed between the storage node electrodes 50 and the upper electrode 60′. The upper electrode 60′, the dielectric layer pattern 55′, and the storage node electrodes 50 may include capacitor elements. At least one of the upper electrode 60′ and the storage node electrodes 50 may be a polysilicon layer or a metal layer.

As described above, according to the present invention, when an upper electrode of a capacitor is formed, it is formed to extend into a peripheral circuit region, so as to reduce a step height difference of a cell region and the peripheral circuit region as compared to the conventional case. As a result, a step height difference profile of an insulating layer to be formed later may have a smooth curve profile. Therefore, a phenomenon of crack generation due to the stress during a planarization process of the insulating layer and the like can be prevented. Further, a single upper electrode is disposed in the cell regions and the peripheral circuit region and thus, a voltage can be applied concurrently. Therefore, when a voltage is applied to the upper electrode of the cells in the cell regions, the voltage will be uniform and will be maintained in a stable state without voltage fluctuation between cells.

While the invention has been particularly shown and described with reference to exemplary embodiments thereof, it will be understood by those of ordinary skill in the art that various changes in form and details may be made therein without departing from the spirit and scope of the invention as defined by the following claims.

What is claimed is:

1. A semiconductor device comprising:
a semiconductor substrate having at least one cell region and a peripheral circuit region;
a plurality of cells disposed on the semiconductor substrate of the cell region, and providing a step height difference region between the peripheral circuit region and the cell region;
an upper electrode covering the substrate having the cells, and having at least one opening exposing a portion of the peripheral circuit region;
a planarized insulating layer overlying the upper electrode; and
contact plugs penetrating the planarized insulating layer and at least one opening of the upper electrode, the contact plugs being electrically connected to the semiconductor substrate.

2. The semiconductor device according to claim 1, wherein the contact plugs are spaced apart from the upper electrode.

3. The semiconductor device according to claim 1, wherein a distance between the contact plugs and the upper electrode is about 0.05 μm to about 0.5 μm.

4. The semiconductor device according to claim 1, wherein the planarized insulating layer includes at least one material selected from the group consisting of a plasma enhanced oxide (PE-Oxide), an undoped silicate glass (USG), a plasma enhanced tetraethyl orthosilicate (PE-TEOS) and high density plasma oxide (HDP-Oxide).

5. A semiconductor device comprising:
a semiconductor substrate having at least one cell region and a peripheral circuit region;
an interlayer insulating layer disposed on the semiconductor substrate;
storage node electrodes disposed on the interlayer insulating layer of the cell region;
an upper electrode covering the substrate having the storage node electrodes, and having at least one opening exposing a portion of the peripheral circuit region;
a planarized insulating layer disposed on the substrate having the upper electrode; and
contact plugs penetrating the planarized insulating layer, the at least one opening of the upper electrode, and the interlayer insulating layer, the contact plugs being electrically connected to the semiconductor substrate.

6. The semiconductor device according to claim 5, wherein the contact plugs are spaced apart from the upper electrode.

7. The semiconductor device according to claim 5, wherein a distance between the contact plugs and the upper electrode is about 0.05 μm to about 0.5 μm.

8. The semiconductor device according to claim 5, wherein the upper electrode is formed to fill the gap regions between the storage node electrodes.

9. The semiconductor device according to claim 5, further comprising a dielectric layer pattern interposed between the storage node electrodes and the upper electrode.

10. The semiconductor device according to claim 5, wherein at least one of the upper electrode and the storage node electrodes is a polysilicon layer or a metal layer.

11. The semiconductor device according to claim 5, wherein the planarized insulating layer includes one material selected from the group consisting of a plasma enhanced oxide (PE-Oxide), an undoped silicate glass (USG), a plasma enhanced tetraethyl orthosilicate (PE-TEOS), a high density plasma oxide (HDP-Oxide).

12. The semiconductor device according to claim 5, further comprising bit lines interposed in the interlayer insulating layer.

13. The semiconductor device according to claim 12, wherein at least one of the contact plugs is disposed to contact the bit lines.

14. A method of fabricating a semiconductor device comprising:
preparing a semiconductor substrate having at least one cell region and a peripheral circuit region;
forming an interlayer insulating layer on the semiconductor substrate;
forming storage node electrodes on the interlayer insulating layer of the cell region;
forming an upper electrode to cover the substrate having the storage node electrodes, the upper electrode having at least one opening exposing a portion of the peripheral circuit region;
forming a planarized insulating layer on the substrate having the upper electrode; and
forming contact plugs penetrating the planarized insulating layer, the at least one opening of the upper electrode, and the interlayer insulating layer, and being electrically connected to the semiconductor substrate.

15. The method according to claim 14, wherein the contact plugs are formed to be spaced apart from the upper electrode.

16. The method according to claim 14, wherein the contact plugs are formed to be spaced apart from the upper electrode with a distance of about 0.05 μm to about 0.5 μm.

17. The method according to claim 14, wherein the upper electrode is formed to fill gap regions between the storage node electrodes.

18. The method according to claim 14, which further comprises forming a dielectric layer pattern between the storage node electrodes and the upper electrode.

19. The method according to claim 14, wherein at least one of the upper electrode and the storage node electrodes comprises a polysilicon layer or a metal layer.

20. The method according to claim 14, wherein forming the planarized insulating layer comprises:
forming an insulating layer over the upper electrode, and having a thickness greater than a height of the storage node electrodes; and
planarizing the insulating layer.

21. The method according to claim 14, wherein the planarized insulating layer is formed to include one material selected from the group consisting of a plasma enhanced oxide (PE-Oxide), an undoped silicate glass (USG), a plasma enhanced tetraethyl orthosilicate (PE-TEOS), and a high density plasma oxide (HDP-Oxide).

22. The method according to claim 14, further comprising forming bit lines inside the interlayer insulating layer.

23. The method according to claim 22, wherein at least one of the contact plugs is formed to contact the bit lines.

24. A method of fabricating a semiconductor device comprising:
forming a first insulating layer on a semiconductor substrate, the semiconductor substrate including a cell region and a peripheral circuit region;
forming storage node electrodes on the first insulating layer in the cell region;
forming an upper electrode over the storage node electrodes, the upper electrode covering both the cell region and the peripheral circuit region;
patterning the upper electrode to expose at least one portion of the peripheral circuit region;
forming a second insulating layer on the upper electrode to have a step height difference profile;
planarizing the second insulating layer; and
forming contact plugs electrically connected to the semiconductor substrate, the contact plugs extending through the first insulating layer and the second insulating layer, wherein the contact plugs are formed in the at least one exposed portion of the peripheral circuit region.

25. The method of claim 24, wherein the second insulating layer is formed to have a height greater than the height of the storage node electrodes.
